(19) United States
(12) Patent Application Publication
(10) Pub. No.: US 2016/0172570 A1
(43) Pub. Date: Jun. 16, 2016

(54) DISPENSER PRINTED MECHANICALLY-ALLOYED P-TYPE FLEXIBLE THERMOELECTRIC GENERATORS

(71) Applicant: THE REGENTS OF THE UNIVERSITY OF CALIFORNIA, Oakland, CA (US)

(72) Inventors: Paul K. Wright, Oakland, CA (US); James W. Evans, Piedmont, CA (US); Deepa Madan, Ellicott City, MD (US); Alic Chen, Oakland, CA (US)

(73) Assignee: THE REGENTS OF THE UNIVERSITY OF CALIFORNIA, Oakland, CA (US)

(21) Appl. No.: 14/967,216

(22) Filed: Dec. 11, 2015

Related U.S. Application Data
(63) Continuation of application No. PCT/US2014/042423, filed on Jun. 13, 2014.
(60) Provisional application No. 61/835,501, filed on Jun. 14, 2013.

(51) Int. Cl. H01L 35/16; H01L 35/18

(52) U.S. Cl. CPC H01L 35/16; H01L 35/18

(57) ABSTRACT

A p-type thermoelectric composite and composite slurries for printing low cost and scalable thermoelectric generator (TEG) devices is presented. The mechanically alloyed Bi_{0.5}Sb_{1.5}Te₃ p-type composite may be enhanced with a ZT additive and a polymer binder. An additive of 2 wt. % to 10 wt. % Tellurium to the composite increased the Seebeck coefficient by approximately 50%. Epoxy is a suitable polymer binder that provides good adhesion strength with minimal curing shrinkage and high mass loading of active filler particles. Different n-type thermoelectric compositions can be used in conjunction with the p-type compositions. Devices with mechanically alloyed Bi_{0.5}Sb_{1.5}Te₃ p-type composites doped with 8 wt. % Te on a flexible wired substrate and n-type Bi-epoxy elements were demonstrated. Potential uses of the devices include power sources for ultra low power needs such as wireless sensor network devices, Peltiers, and thermoelectric coolers.

### CROSS-REFERENCE TO RELATED APPLICATIONS

This application is a 35 U.S.C. §111(a) continuation of PCT international application number PCT/US2014/042423 filed on Jun. 13, 2014, incorporated herein by reference in its entirety, which claims priority to, and the benefit of, U.S. provisional patent application Ser. No. 61/835,501 filed on Jun. 14, 2013, incorporated herein by reference in its entirety. Priority is claimed to each of the foregoing applications.

The above-referenced PCT international application was published as PCT International Publication No. WO 2014/201430 on Dec. 18, 2014, which publication is incorporated herein by reference in its entirety.

### STATEMENT REGARDING FEDERALLY SPONSORED RESEARCH OR DEVELOPMENT

Not Applicable

### INCORPORATION-BY-REFERENCE OF MATERIAL SUBMITTED IN A COMPUTER PROGRAM APPENDIX

Not Applicable

### BACKGROUND

1. Field of the Disclosure

This disclosure pertains generally to thermoelectric composite compositions and synthesis schemes, and more particularly to mechanically alloyed p-type thermoelectric composite slurries for use with scalable printing deposition techniques. The compositions can be used to produce thermoelectric generation devices such as power sources for ultra low power devices and thermoelectric coolers.

2. Background

A significant amount of heat is released into the environment with industrial systems such as heat engines and pipes carrying hot fluids. For example, most of the world's power is generated by heat engines that use fossil fuel combustion as a heat source and these engines typically operate at 30%-40% efficiency. A large proportion of this heat is lost to the environment and wasted. Co-generation plants have been used to improve the overall efficiency by providing electricity as well as heat for the creation of steam or for other heating purposes. This heat or heated fluid is typically transported in pipes and used for many industrial and residential applications.

Wireless sensors such as steam/gas-leak sensors, pressure sensors, and temperature sensors are often used for condition monitoring of such pipes. The power requirements for these sensors are only a few microwatts and primary batteries are used to meet this demand. Likewise, wireless sensor networks (WSNs) are a promising technology for active monitoring in residential, industrial and medical settings. While the power demands for these networks can be partially alleviated through electronics, any primary battery that is used will have a limited lifetime. Battery replacement cost and labor cost make large scale use of these types of sensors infeasible.

Thermoelectric generators can potentially be used to generate electricity from this low-grade waste heat and may play a role in powering condition monitoring sensors around engines, motors, and pipes etc. Thermoelectric modules, which utilize the temperature difference between the hot pipe and the ambient air to generate power, could be used for powering these sensors. Solid state thermoelectric generators (TEGs) have been shown to be reliable, have no moving parts, are CO₂ emission free and could play an important role in a globally sustainable energy solution.

In order to be used for powering wireless sensor networks, the thermoelectric generator (TEG) should be able to provide power at certain desired voltage levels. A high voltage output requires a large number of devices to be packed into a small area. In addition, the electrical resistance of the device must be low in order to maximize power output, thus requiring short element lengths. However, small element lengths pose difficulties in maintaining temperature differences across the device. Therefore, a trade-off occurs between device element length and power output, which ultimately depends on the particular TEG application. While TEG device geometry is dependent on the selected application, high-density and high-aspect-ratio arrays may be required for low-temperature TEG applications.

Devices utilizing waste heat to generate power should also have a low cost in order to be competitive. Conventional pick and place methods of manufacturing TEG devices are labor, material and energy intensive. The alternative micro-fabrication technology involves expensive and complicated processes like lithography and thin-film deposition and these processes are limited to micro-scale approaches. These methods also have limited cost-effective scalability for manufacturing application-specific thermoelectric generation devices.

Furthermore, the performance of these existing devices depends on both the material properties and the device geometry and their efficiency is low. The efficiency of thermoelectric generators is governed by the dimensionless figure of merit, ZT, which depends on the properties of the constituent materials. It is defined as ZT=α²σTk⁻¹, where α, σ, k, and T are the Seebeck coefficient, electrical conductivity, thermal conductivity and absolute temperature, respectively. Increasing the ZT beyond current levels in commercial thermoelectric materials has been challenging since the thermoelectric parameters of ZT are generally interdependent.

Accordingly, there is a need for efficient, inexpensive, scalable and stable thermoelectric generation material compositions and devices that can provide power from waste heat and provide power to support sensor network devices and a broad range of additional applications.

### BRIEF SUMMARY

The basic unit of thermoelectric converters is a coupling of n-type (electron-transporting) and p-type (hole-transporting) elements. When the coupling is exposed to a temperature gradient (ΔT), an electrostatic potential (ΔV) is established when mobile charge carriers at the hot side diffuse to the cold side, known as the Seebeck effect. The converse is also possible with an applied voltage by absorbing energy on one side and releasing it on the other, known as the Peltier effect.

In this context, the disclosed p-type thermoelectric materials can be used with any suitable n-type material to optimize the efficiency of the thermoelectric device. The disclosed materials are also capable of being applied to a substrate such as inks to form printed films of various scales and dimensions.

Printing of high-aspect-ratio thermoelectric generator devices requires thermoelectric materials that are readily synthesized, air stable, and a reliable solution process that is able to create patterns on large substrate areas. In this regard, polymer thermoelectric composites are very attractive, as they require relatively simple manufacturing processes. However, the ZT of polymer based composite materials is generally very low. Efficient thermoelectric materials should have high Seebeck coefficients (a) to provide sufficient voltages, high electrical conductivities (r) to allow for electric current, and low thermal conductivities (j) to minimize heat losses.

Manufacturing methods such as direct-write printing use additive processing steps, thus reducing material waste and the cost per unit area. Printing can also be an automated process that can be used to print high-aspect-ratio devices with minimum labor. The present disclosure describes the synthesis of high ZT thermoelectric composite slurries and their application in printing high aspect ratio, high density and cost effective TEG devices. The materials and processes described may also be used to print other thermoelectric devices such as coolers and peltiers.

In order to realize practical thermoelectric devices, both p-type and n-type elements connected in series are preferred to achieve reasonable efficiency. Printable polymer Mechanically Alloyed (MA) p-type thermoelectric composite slurries and n-type composite slurries are provided that can be used as printable inks or film forming materials to be deposited on a substrate. A Bi_{0.5}Sb_{1.5}Te₃ composite was chosen as the starting p-type thermoelectric material and its ZT is preferably enhanced by the addition of an extra Te or Bi additive in one embodiment. It has been shown that the addition of approximately 2 weight percent (wt. %) to approximately 8 weight percent (wt. %) of extra Te to the mechanical alloy (MA) Bi_{0.5}Sb_{1.5}Te₃ helps to achieve a higher ZT for the composite film. For p-type Bi_{0.5}Sb_{1.5}Te₃ alloys, it is well-known that holes are created by the anti-structure defects generated by the occupation of Te sites with the Bi and Sb atoms. The element Te as an additive helps to reduce the carrier concentration and improve the Seebeck coefficient by inhibiting the formation of anti-structure defects during mechanical alloying.

Epoxy was chosen as a polymer binder as it gives good adhesion strength with minimal curing shrinkage and provides high mass loading of active filler particles. The element Bi has high electrical conductivity that may help to improve the electrical conductivity of composite films. Therefore, a Bi-epoxy composition was selected as the preferred n-type composite thermoelectric material. However, Bi₂Te₃ and Se-epoxy can also be used as an n-type material.

A high aspect ratio circular device design that maintains the temperature difference across the device and achieves a reasonable power output is used as an illustration. For example, a circular TEG device can be wrapped around a heated pipe, one side of the TEG in contact with hot pipe and other side exposed to the ambient environment and the device generates power output by exploiting this temperature difference.

Thermoelectric generator prototypes were printed on a custom designed polyimide substrate with thick metal contacts for evaluation. The prototype TEG device produced a power in the microwatt range that is sufficient to power the ultra low power application devices like wireless sensor network devices (WSNs).

Further aspects of the disclosure will be brought out in the following portions of the specification, wherein the detailed description is for the purpose of fully disclosing preferred embodiments of the materials and apparatus without placing limitations thereon.

### BRIEF DESCRIPTION OF THE SEVERAL VIEWS OF THE DRAWINGS

The disclosure will be more fully understood by reference to the following drawings which are for illustrative purposes only:

FIG. 1 is a schematic flow diagram of one embodiment of a method for producing a MA Bi_{0.5}Sb_{1.5}Te₃ p-type slurry according to the technology of the present disclosure.

FIG. 2 depicts an embodiment of a planar dispenser printed p-type thermoelectric on a flexible PCB substrate according to the technology of the present disclosure.

FIG. 3 depicts an embodiment of a coiled dispenser printed p-type thermoelectric on a flexible PCB substrate according to the technology of the present disclosure.

FIG. 4 is a graph of electrical conductivity of dispenser printed MA Bi_{0.5}Sb_{1.5}Te₃ composite films as a function of extra Te wt. %.

FIG. 5 is a graph of Seebeck coefficient of dispenser printed MA Bi_{0.5}Sb_{1.5}Te₃ composite films as a function of extra Te wt. %.

FIG. 6 is a graph of carrier concentration of dispenser printed MA Bi_{0.5}Sb_{1.5}Te₃ composite films as a function of extra Te wt. %.

FIG. 7 is a graph of power factor of dispenser printed MA Bi_{0.5}Sb_{1.5}Te₃ composite films as a function of extra Te wt. %.

### DETAILED DESCRIPTION

The material compositions and systems of the present disclosure are designed for use with the conversion of thermal energy to electrical energy for either the generation of electric power or for electronic refrigeration. The disclosed p-type thermoelectric materials can be used with any suitable n-type materials and can be put in any thermoelectric device configuration. It will be appreciated that the methods may vary as to the specific steps and sequence and the apparatus and composition may vary as to elements and structure without departing from the basic concepts as disclosed herein. The method steps are merely exemplary of the order in which these steps may occur. The steps may occur in any order that is desired, such that it still performs the goals of the claimed technology.

Embodiments of a typical thermoelectric apparatus of the technology generally includes three main components: 1) a Mechanically Alloyed (MA) p-type thermoelectric composite with a dopant additive of 2 weight percent (wt. %) to 10 weight percent (wt. %) of the total composite of a ZT enhancing material and a polymer binder; 2) an n-type thermoelectric composite with a polymer binder; and 3) a current collector disposed on a substrate.

To illustrate the compositions and devices, printable polymer mechanically alloyed p-type thermoelectric composite slurries and n-type composite slurries are provided that can be used as printable inks or film forming materials to be deposited on a substrate. The materials can be placed or deposited on a substrate made from a material that allows the transfer of heat. The substrate may be rigid, or it can be flexible such as a polyimide sheet. Preferably, both deposited p-type and n-type elements are connected in series to achieve reasonable device efficiency.

The p-type thermoelectric composite material is preferably elemental bismuth, antimony, and tellurium mechanically alloyed in the molar ratio of Bi_{0.5}Sb_{1.5}Te₃.

A dopant of between 2 wt. % to 10 wt. % of additional Te is preferably added to the mechanically alloyed composite material to increase the Seebeck coefficient of the material. Although Te is preferred, other ZT enhancing dopants such as Bi or Se can be used.

The n-type material used in a device is preferably bismuth mixed with a binder such as epoxy. Although Bi-epoxy is preferred, other n-type materials such as Bi₂Te₃ and Se-epoxy can also be used.

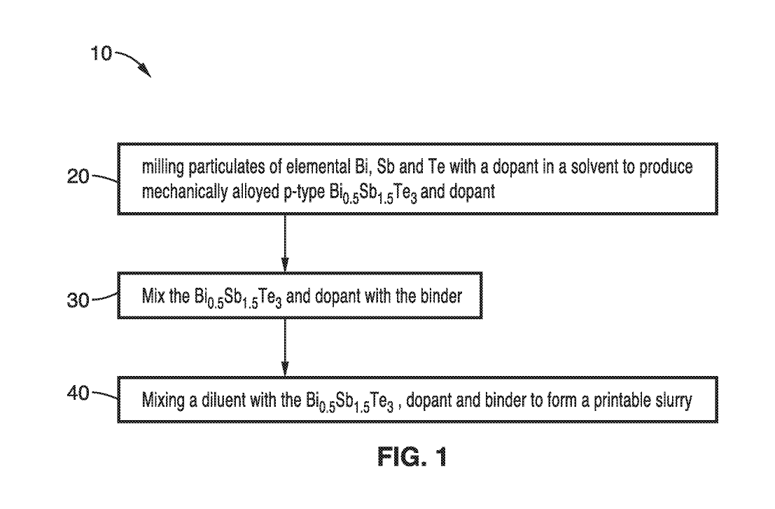

Turning now to FIG. 1, one embodiment of a method 10 for producing a printable slurry of a preferred p-type thermoelectric material is schematically shown. The slurry may be produced by milling particulates of elemental Bi, Sb and Te with a dopant in a solvent to produce mechanically alloyed p-type Bi_{0.5}Sb_{1.5}Te₃ and a dopant powder at block 20. The mechanically alloyed material is then mixed with a binder such as epoxy at block 30. Finally, the Bi_{0.5}Sb_{1.5}Te₃, dopant and binder are mixed with a diluent to form a printable slurry at block 40.

Preferably, the materials are milled to a narrow range of particle sizes. For example, the Bi_{0.5}Sb_{1.5}Te₃ and a dopant powder can be milled to a particle size ranging from between 1 μm to 200 μm. Similar milling can take place with the n-type materials as well. The material formulations may also include mixing in a hardener and a catalyst along with the binder.

Many different device designs can be formulated for various applications and the designs can be optimized. The electrical resistance and the temperature difference across the device depend on the element length of the device. Electrical resistance increases with increase in element length resulting in lower power output. The temperature difference across the device increases with an increase in element length resulting in higher power output. Therefore, a trade-off occurs between an application specific optimized device length and power output.

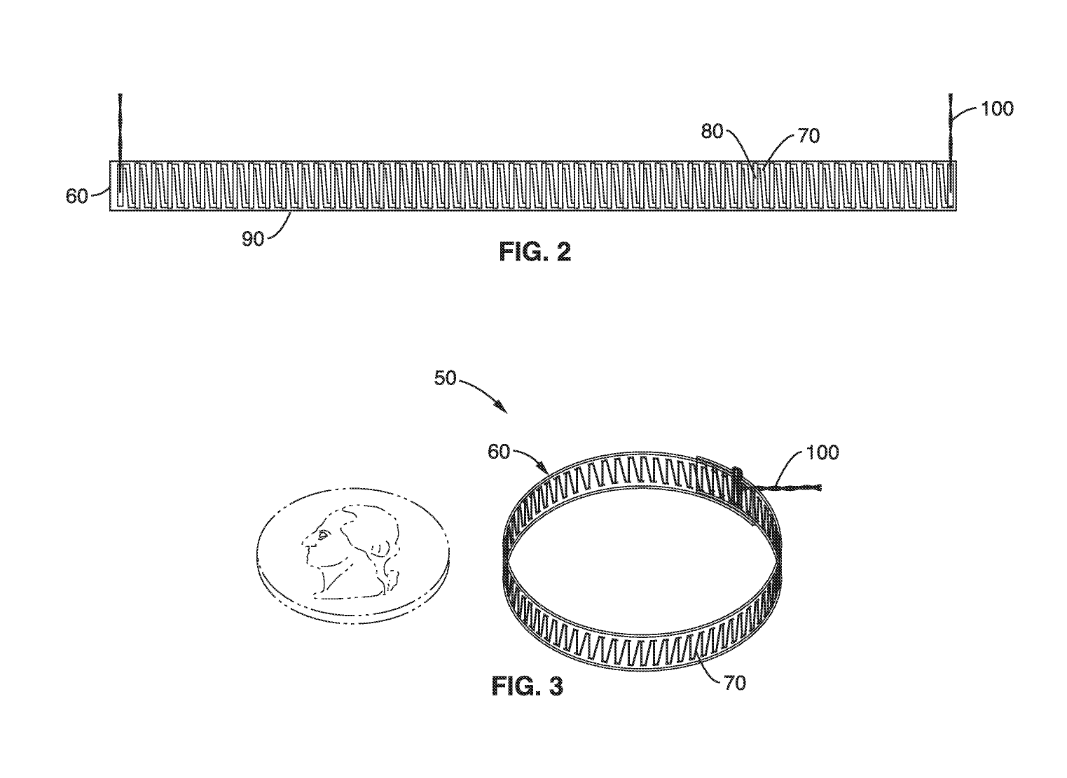

The prepared n-type and p-type inks can be deposited on a substrate using conventional deposition techniques. Although the device geometry of a TEG depends on the particular application, high density and high aspect ratio configurations are very desirable for various low waste heat applications. For example, as shown in FIG. 2 and FIG. 3, devices can be deposited on substrates of flexible sheets or strips that can be easily mounted on hot surfaces or wrapped around pipes carrying hot fluid to generate electricity to power condition monitoring sensors. The thermoelectric generator 50 illustrated in FIG. 2 and FIG. 3 has a substrate 60 with a printed overlay of a p-type material 70 and an overlay of an n-type material 80 that are joined to electrical contacts 90 and leads 100.

In one preferred embodiment, a thermoelectric generator (TEG) apparatus can be produced that has (a) a substrate; (b) a number of electrically conductive contacts attached to the substrate; (c) a printed overlay electrically coupled to the contacts formed from (i) a cured slurry of a Mechanically Alloyed (MA) p-type thermoelectric composite of Bi_{0.5}Sb_{1.5}Te₃ with a dopant additive of 2 wt. % to 10 wt. % of the total composite of a ZT enhancing material; and (ii) a polymer binder; and (d) a printed overlay electrically coupled to the contacts formed from (i) a cured slurry of a n-type thermoelectric composite of Bi and (ii) a polymer binder.

The technology may be better understood with reference to the accompanying examples, which are intended for purposes of illustration only and should not be construed as in any sense limiting the scope of the present invention as defined in the claims appended hereto.

### Example 1

In order to demonstrate the operational principles of the thermoelectric compositions and methods, a slurry of p-type Bi_{0.5}Sb_{1.5}Te₃ was produced using chunks (1 mm to 12 mm size) of elemental bismuth, antimony, and tellurium that were mechanically alloyed in the desired molar ratio. A high-energy planetary ball-mill (Torrey Hills ND 0.4 L) was used for mechanical alloying. To improve the thermoelectric properties of the MA Bi_{0.5}Sb_{1.5}Te₃, varying amounts of Te (2 to 10 wt. %) were used as a dopant. In addition to mechanical alloying, wet grinding was used to reduce the average particle size to approximately 10 μm.

Thermoelectric composite inks were made using Bi_{0.5}Sb_{1.5}Te₃ as active particles and a commercial epoxy resin as the polymer matrix. A Vortex mixer and an ultrasonic bath were used to disperse the particles and mix the active particles in the polymer to form well dispersed slurries. Composite films between 100 μm to 120 μm thick were then printed onto glass substrates using a dispenser printer. The films were then cured at 250° C. for 12 hours to form thick films that were used for measuring thermoelectric properties.

### Example 2

To further demonstrate the preparation and capabilities of the thermoelectric composite inks, Elemental Bi (99.999%, 1 to 5 mm balls), Sb(99.999%, 1 to 5 mm balls) and Te (99.999%, 1 mm to 12 mm chunks) (Sigma Aldrich Corporation) were selected as starting materials for mechanical alloying. A molar ratio of Bi, Sb and Te was used to form mechanically alloyed (MA) p-type Bi_{0.5}Sb_{1.5}Te₃. Te was chosen as a dopant to improve the overall thermoelectric properties of the MA Bi_{0.5}Sb_{1.5}Te₃. Therefore, varying amounts of Te were added to the alloyed material, ranging incrementally from between 2 to 10 wt % of the total weight of Bi_{0.5}Sb_{1.5}Te₃.

An average particle size of approximately 10 μm was preferred in the preparation of dispenser print inks. Stainless steel jars containing 100 ml of isopropanol and 10 mm diameter balls were used for the ball milling process. The ball to powder weight ratio was kept at 15:1. All powder handling was performed in an argon-filled glove box, in which the oxygen level was kept below 5 ppm to prevent oxidation of the powders. Mechanical alloying was carried out in a planetary ball mill apparatus (Torrey Hills ND 0.4) at 315 rpm for 14 hours in a purified argon atmosphere. The particle size of the as-milled powders was measured using a Coulter LS-100 laser diffraction particle size analyzer. The milled particle size ranged between 1 μm to 200 μm. To further reduce the particle size, the as-milled powders were ball milled again with 3 mm stainless steel balls at a ball-to-powder mass ratio of 10:1 with isopropyl alcohol (1:1 fluid to powder ratio) at 245 rpm for 2 hours.

Thermoelectric composite slurries were made using Bi_{0.5}Sb_{1.5}Te₃ as active particles and commercial epoxy resin as polymer matrix. EPON 862 diglycidyl ether of bisphenol f epoxy together with methylhexahydrophthalic anhydride MHHPA (Dixie Chemicals, Inc.) hardener was used as the epoxy resin system. The ratio of epoxy-to-hardener was 1:0.85 based on the epoxide equivalent weight of the resin and the hydroxyl equivalent weight of the hardener. 1-cyanoethyl-2-ethyl-4-methylimidazole 2E4MZCN (Sigma-Aldrich, Inc.) was used as the catalyst. Between 10 to 20 wt. % of butyl glycidyl ether Heloxy 61 (Hexion Specialty Chemicals, Inc.) was employed in the resin blend as a reactive diluent to adjust viscosity of the slurry without compromising the desired properties. The slurry was mixed using a vortex mixer and an ultrasonic bath to disperse the particles. The thermoelectric inks were then printed on glass substrates to form 100 μm to 120 μm thick films using dispenser printing, and cured at 250° C. for 12 hours to form solid thick films.

### Example 3

X-ray diffraction was performed on MA Bi_{0.5}Sb_{1.5}Te₃ and MA Bi_{0.5}Sb_{1.5}Te₃ with 8 wt. % extra Te powder materials using a Siemens (D5000) X-ray generator using monochromatized CuKα (λ=1.5418 Å) radiation. The XRD peaks for both graphs were consistent with the standard pattern of Bi_{0.5}Sb_{1.5}Te₃ (JCPDS49-1713), confirming the formation of MA Bi_{0.5}Sb_{1.5}Te₃. The rhombohedral crystal structure of MA Bi_{0.5}Sb_{1.5}Te₃ with space group (R3m) remained unchanged with the addition of 8 wt. % extra Te.

Scanning electron microscope (SEM) images of filler particles after mechanical alloying and wet grinding were obtained show an average particle size of less than 5 μm. SEM images of a cured Bi_{0.5}Sb_{1.5}Te₃/epoxy dispenser printed composite film suggested that the epoxy polymer binder forms a solid, dense matrix when mixed and cured with active Bi_{0.5}Sb_{1.5}Te₃ particles. It also indicated that active particles are uniformly distributed in the polymer matrix.

The dispenser printable thermoelectric composite slurries were made by mixing MA Bi_{0.5}Sb_{1.5}Te₃ p-type active material in epoxy resin polymer binder, which is a well-known electrically conductive adhesive. However, to form a conductive path in composite systems, the volume fraction of conductive active particles in the polymer matrix should be higher than percolation threshold. Empirical studies show that the filler particles to epoxy volume ratio should be about 45% to 55% in order to form the conductive paths. The highest volume ratio of active particles to polymer achieved was 48% to 52%, beyond which crack formation was observed in the cured film.

This higher volume ratio resulted in compact films with minimal cure shrinkage and overall good thermoelectric properties. The properties of the thermoelectric composite materials are a function of the polymer matrix and the active particles. Thermoelectric composite materials should have high electrical conductivity and Seebeck coefficient but low thermal conductivity. The electrical conductivity should be high to allow good carrier transport; Seebeck coefficient should be high to provide sufficient voltage; and thermal conductivity should be low to minimize heat losses.

The shrinkage of the polymer matrix upon curing effectively packs the fillers involved. The curing of dispenser printed films was done in the temperature range of 150° C. to 350° C. At curing temperatures of 150° C. and 200° C., films did not give adequate thermoelectric properties. One possible reason is the inadequate shrinkage of the polymer matrix upon curing to pack filler particles. Cracking was observed in films cured at or above 300° C. Therefore, p-type dispenser printed films were cured at 250° C. The curing was done for 12 hours to facilitate annealing with the objective of reducing the defects, and hence the carrier concentration, and improving the Seebeck coefficient.

### Example 4

Device fabrication was demonstrated with a single leg planar TEG that was dispenser printed on a flexible substrate. A flexible printed circuit board (Flex-PCB) was used as a substrate. The Flex-PCB consisted of nickel and gold plated copper traces on a flexible polyimide substrate. Thick gold plated nickel and copper metal contacts resulted in reduced electrical contact resistance between metal contacts and the printed TE elements. Flexible polyimide has low thermal conductivity that helps to maintain temperature difference across the device, electrical insulation helps to separate the gold contacts and high temperature tolerance make curing feasible for printed elements at high temperature.

The planar thermoelectric device was fabricated from dispenser printed MA p-type Bi_{0.5}Sb_{1.5}Te₃ with 8 wt. % extra Te polymer composite slurries. Printed TEG devices were cured in an Argon/vacuum oven at 250° C. Electrical connections were made using silver epoxy and electrical wires. The printed prototype device was tested using a custom testing apparatus within 24 hours of curing.

Thermoelectric heater/coolers (9500/127/040 B, Ferrotech Corp.) were mounted on two aluminum plates to provide surfaces for cooling and heating. The printed TEG was positioned between the plates and a temperature difference was applied across the device. Once the device reached steady state, the open circuit voltage of the device was measured using a digital multimeter. A variable load resistance was then connected in series with the device and voltage measurements were taken at multiple load resistances. The power was calculated based on the measured voltage and load resistance at various temperature differences.

### Example 5

To further demonstrate the apparatus, the thermoelectric properties of n-type Bi-epoxy and p-type Bi_{0.5}Sb_{1.5}Te₃ with 8 wt. % extra Te-epoxy dispenser printed films were evaluated as a function of temperature. A circular TEG device was tested with a device on a flexible printed circuit board (Flex-PCB) substrate that contained nickel and gold plated copper traces that were fabricated on a flexible polyimide substrate manufactured by Rigiflex Technology, Inc. A polyimide substrate with metal electrodes was chosen due to its flexibility, electrical insulation, high temperature tolerance, and low thermal conductivity (0.12 W/m-K). N-type Bi-epoxy and p-type MA Bi_{0.5}Sb_{1.5}Te₃ composite inks were dispenser printed onto the substrate to form lines spanning across the inner and the outer contacts. Thick metal contacts resulted in reduced electrical contact resistance between metal contacts and printed TE elements. Printed lines on the flex PCB were cured in an argon/vacuum oven at 250° C.

The circular TEG device was placed in such a manner that one side of thermo elements rested on hot side peltiers and other side on cold side. A series of temperature differences was applied across the dispenser printed prototype device. Temperatures at the both ends of the elements were monitored to ensure that a steady state was reached and the open circuit voltage was measured. Closed circuit voltage measurements were also taken at multiple load resistance values. The power output was calculated using the measured voltage and load resistance at various temperature differences.

N-type Bi-epoxy and p-type MA Bi_{0.5}Sb_{1.5}Te₃-epoxy slurries were also dispenser printed as thick films on a glass substrate for thermoelectric characterization purposes and cured at 250° C. and film properties were measured. The Seebeck coefficient was calculated by measuring the temperature difference across the sample and the open circuit voltage resulting from the temperature difference.

The thermoelectric composite material properties are function of polymer matrix and active particles. Bi has approximately 1 order of magnitude higher electrical conductivity (9000 S/cm) as compared to bulk Bi_{0.5}Sb_{1.5}Te₃ (1300 S/cm). The electrical conductivity of n-type Bi epoxy as well as MA p-type Bi_{0.5}Sb_{1.5}Te₃ epoxy composites was almost 2 orders of magnitude lower than the bulk due to the insulating nature of the epoxy polymer that was present in composite films. Additionally, the Bi-epoxy composite demonstrated a 1 order of magnitude higher electrical conductivity (110 S/cm) as compared to MA p-type Bi_{0.5}Sb_{1.5}Te₃ with 8 wt. % extra Te-epoxy films (11 S/cm).

Negligible variation in the film properties with temperature is desirable. The results indicated that the film properties of the n-type and p-type composite films do not deteriorate in the temperature range of between 20° C. and 80° C. and the devices fabricated using these materials can operate in this temperature range.

### Example 6

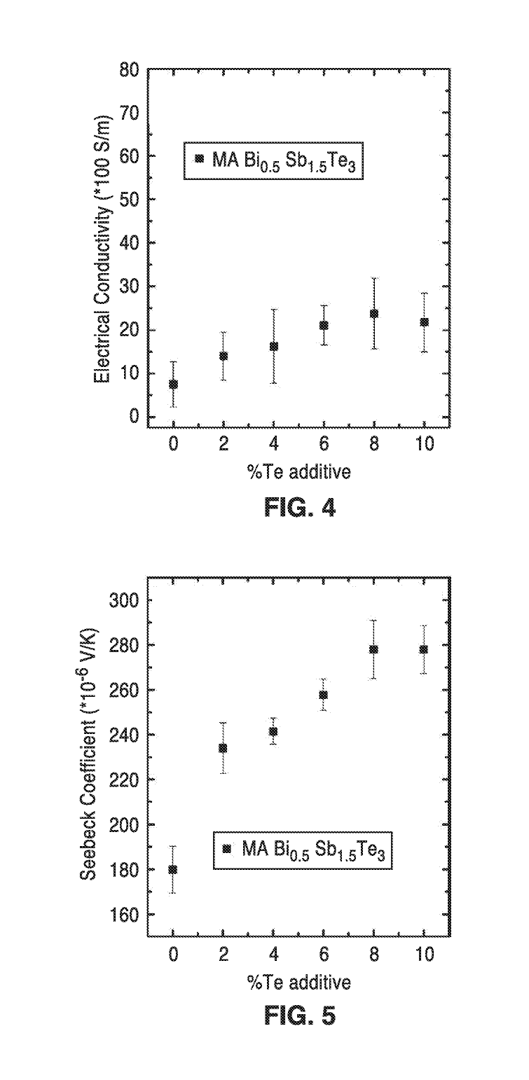

The thermoelectric properties of p-type MA Bi_{0.5}Sb_{1.5}Te₃ composite films with varying dopant concentrations cured at 250° C. for 12 hours were studied at room temperature and are shown in FIG. 4 through FIG. 7.

It is clear from FIG. 4 that the dispenser printed MA Bi_{0.5}Sb_{1.5}Te₃ composite films have electrical conductivities (12 S/cm) that are 2 orders of magnitude lower as compared to bulk Bi_{0.5}Sb_{1.5}Te₃ (1300 S/cm). The lower electrical conductivity is due to the non-conducting epoxy polymer matrix. The observed decrease in electrical conductivity may also be due to grain boundary scattering, which causes the carrier mobility to be lower.

The addition of the Te dopant also did not help to improve electrical conductivity significantly. The slight increase in the electrical conductivity with addition of Te is possibly due to increased grain coalescence facilitated by the presence of the extra Te which has a lower melting point compared to the Bi_{0.5}Sb_{1.5}Te₃ material.

FIG. 5 is a graph showing Seebeck coefficient variations with respect to Te as an additive. The positive value of the Seebeck coefficient confirms the material as p-type. For the stoichiometric MA Bi_{0.5}Sb_{1.5}Te₃ composite films, the Seebeck coefficient is the same (200 μV/K1) as reported for bulk material. According to EMT the Seebeck coefficient of a composite system depends on the effective electrical and thermal conductivity of the composite system. Because the electrical conductivity of the insulating polymer is zero, the effective Seebeck coefficient of the composite system is the same as that of MA Bi_{0.5}Sb_{1.5}Te₃ and is related to carrier concentration only.

Approximately 50% improvement in the Seebeck coefficient was observed as a result of adding extra Te. Antisite defects are created in the Bi_{0.5}Sb_{1.5}Te₃ alloy as Te sites are occupied by Bi and Sb atoms. The “hole” concentration of p-type Bi_{0.5}Sb_{1.5}Te₃ alloy depends on the antisite defects and on the degree of Te deficiency in the stoichiometric composition.

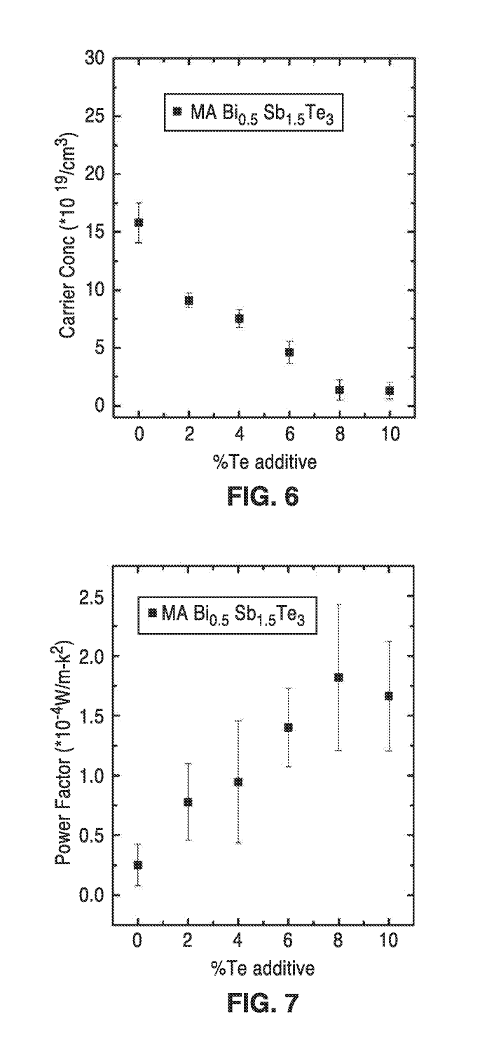

Antisite defect concentration decreases with the addition of extra Te since the Te deficiency sites are replaced by the extra Te. As a result, the Seebeck coefficient increases. The Hall coefficient and carrier concentration measurements were done using Ecopia-300. Hall effect measurements confirmed slightly lower bulk carrier concentration for films with extra Te, as shown in FIG. 6. Therefore, the Seebeck coefficient is higher for films that contain the additional 8 wt. % Te.

FIG. 7 shows that the power factor is highest for MA Bi_{0.5}Sb_{1.5}Te₃ with 8 wt. % extra Te composite films (1.8×10⁻⁴ W/(m K²)). The addition of 10% extra Te did not help to improve the thermoelectric materials properties any further. Therefore, the MA Bi_{0.5}Sb_{1.5}Te₃ with 8 wt. % extra Te composition was selected for making the TEGs. A transient plane source with C-therm TCi thermal conductivity analyzer was used to measure the thermal conductivity. The thermal conductivity of MA Bi_{0.5}Sb_{1.5}Te₃ with 8 wt. % extra Te dispenser printed film was 0.24 W/(m K).

Lower thermal conductivity as compared to the bulk (1.1 W/(m K)) is due to the insulating nature of epoxy. Additionally, fine grain (5 μm) active filler particles increase the potential barrier scattering that also contributes to lower thermal conductivity. A maximum ZT of 0.2 was achieved for dispenser printed MA Bi_{0.5}Sb_{1.5}Te₃ with 8 wt. % Te composite films.

From the discussion above it will be appreciated that the technology described herein can be embodied in various ways, including the following:

1. A p-type thermoelectric composition, comprising stoichiometric Bi_{0.5}Sb_{1.5}Te₃.

2. The composition of any preceding embodiment, wherein the Bi_{0.5}Sb_{1.5} Te₃ composition further comprises an additive of a ZT enhancing material.

3. The composition of any preceding embodiment, wherein the additive comprises Tellurium.

4. The composition of any preceding embodiment, wherein the Tellurium additive comprises 2 wt. % to 10 wt. % of the total composite.

5. The composition of any preceding embodiment, wherein the additive comprises Bismuth.

6. The composition of any preceding embodiment, wherein the Bismuth additive comprises 2 wt. % to 10 wt. % of the total composite.

7. The composition of any preceding embodiment, wherein the Bi_{0.5}Sb_{1.5}Te₃ composition further comprises a polymer binder.

8. The composition of any preceding embodiment, wherein the polymer binder comprises epoxy.

9. The composition of any preceding embodiment, wherein the Bi_{0.5}Sb_{1.5} Te₃ composition further comprises a hardener and a catalyst.

10. The composition of any preceding embodiment, wherein the Bi_{0.5}Sb_{1.5}Te₃ composition is mechanically alloyed from elemental Bi, Sb and Te.

11. A method for producing a printable thermoelectric material, comprising: (a) milling particulates of elemental Bi, Sb and Te with a dopant in a solvent to produce mechanically alloyed p-type Bi_{0.5}Sb_{1.5}Te₃ and dopant; (b) mixing the Bi_{0.5}Sb_{1.5}Te₃ and dopant with a binder; and (c) mixing a diluent with the Bi_{0.5}Sb_{1.5}Te₃, dopant and binder to form a printable slurry.

12. The method of any preceding embodiment, wherein the dopant additive comprises 2 wt. % to 10 wt. % of the total Bi_{0.5}Sb_{1.5}Te₃ composite of Te, Bi or Se.

13. The method of any preceding embodiment, further comprising milling the Bi_{0.5}Sb_{1.5}Te₃ and dopant to a particle size ranging between 1 μm to 200 μm

14. The method of any preceding embodiment, further comprising: mixing a hardener and a catalyst with the with the Bi_{0.5}Sb_{1.5}Te₃, dopant and binder.

15. The method of any preceding embodiment, further comprising: mixing particles of the Bi_{0.5}Sb_{1.5}Te₃ and dopant with the binder to a binder volume ratio within the range of 45% to 55%.

16. A thermoelectric generator (TEG) apparatus, comprising: (a) a substrate; (b) a plurality of electrically conductive contacts attached to the substrate; and (c) a printed overlay of p-type material electrically coupled to the contacts, the overlay comprising: (i) a cured slurry of a Mechanically Alloyed (MA) p-type thermoelectric composite of Bi_{0.5}Sb_{1.5}Te₃; (ii) a dopant additive of 2 wt. % to 10 wt. % of the total composite of a ZT enhancing material; and (iii) a polymer binder; and (d) a printed overlay of n-type material electrically coupled to the contacts.

17. The apparatus of any preceding embodiment, wherein the n-type material is a material selected from the group of materials consisting of Bi, Bi₂Te₃ and Se.

18. The apparatus of any preceding embodiment, the n-type material further comprising a polymer binder.

19. The apparatus of any preceding embodiment, wherein the dopant of ZT enhancing material is a material selected from the group of materials consisting of Te, Bi, and Se.

20. The apparatus of any preceding embodiment, wherein the slurry of Bi_{0.5}Sb_{1.5}Te₃, dopant and binder has a particle size ranging between 1 μm to 200 μm.

Although the description herein contains many details, these should not be construed as limiting the scope of the disclosure but as merely providing illustrations of some of the presently preferred embodiments. Therefore, it will be appreciated that the scope of the disclosure fully encompasses other embodiments which may become obvious to those skilled in the art.

In the claims, reference to an element in the singular is not intended to mean “one and only one” unless explicitly so stated, but rather “one or more.” All structural, chemical, and functional equivalents to the elements of the disclosed embodiments that are known to those of ordinary skill in the art are expressly incorporated herein by reference and are intended to be encompassed by the present claims. Furthermore, no element, component, or method step in the present disclosure is intended to be dedicated to the public regardless of whether the element, component, or method step is explicitly recited in the claims. No claim element herein is to be construed as a “means plus function” element unless the element is expressly recited using the phrase “means for”. No claim element herein is to be construed as a “step plus function” element unless the element is expressly recited using the phrase “step for”.

What is claimed is:

1. A p-type thermoelectric composition, comprising a stoichiometric Bi_{0.5}Sb_{1.5}Te₃ composition.

2. The composition of claim 1, wherein said Bi_{0.5}Sb_{1.5}Te₃ composition further comprises an additive of a ZT enhancing material.

3. The composition of claim 2, wherein said additive comprises Tellurium.

4. The composition of claim 3, wherein said Tellurium additive comprises 2 wt. % to 10 wt. % of the total composite.

5. The composition of claim 2, wherein said additive comprises Bismuth.

6. The composition of claim 5, wherein said Bismuth additive comprises 2 wt. % to 10 wt. % of the total composite.

7. The composition of claim 2, wherein said Bi_{0.5}Sb_{1.5}Te₃ composition further comprises a polymer binder.

8. The composition of claim 7, wherein said polymer binder comprises epoxy.

9. The composition of claim 7, wherein said Bi_{0.5}Sb_{1.5}Te₃ composition further comprises a hardener and a catalyst.

10. The composition of claim 1, wherein said Bi_{0.5}Sb_{1.5}Te₃ composition is mechanically alloyed from elemental Bi, Sb and Te.

11. A method for producing a printable thermoelectric material, comprising:
(a) milling particulates of elemental Bi, Sb and Te with a dopant in a solvent to produce mechanically alloyed p-type Bi_{0.5}Sb_{1.5}Te₃ and dopant;
(b) mixing the Bi_{0.5}Sb_{1.5}Te₃ and dopant with a binder; and
(c) mixing a diluent with the Bi_{0.5}Sb_{1.5}Te₃, dopant and binder to form a printable slurry.

12. The method of claim 11, wherein the dopant comprises 2 wt. % to 10 wt. % of the total Bi_{0.5}Sb_{1.5}Te₃ composite of Te, Bi or Se.

13. The method of claim 11, further comprising:
milling the Bi_{0.5}Sb_{1.5}Te₃ and dopant to a particle size ranging between 1 μm to 200 μm.

14. The method of claim 11, further comprising:
mixing a hardener and a catalyst with the with the Bi_{0.5}Sb_{1.5}Te₃, dopant and binder.

15. The method of claim 11, further comprising:
mixing particles of the Bi_{0.5}Sb_{1.5}Te₃ and dopant with the binder to a binder volume ratio within the range of 45% to 55%.

16. A thermoelectric generator (TEG) apparatus, comprising:
(a) a substrate;
(b) a plurality of electrically conductive contacts attached to said substrate; and
(c) a printed overlay of p-type material electrically coupled to the contacts, the overlay comprising:
(i) a cured slurry of a Mechanically Alloyed (MA) p-type thermoelectric composite of Bi_{0.5}Sb_{1.5}Te₃;
(ii) a dopant additive of 2 wt. % to 10 wt. % of the total composite of a ZT enhancing material; and
(iii) a polymer binder; and
(d) a printed overlay of n-type material electrically coupled to the contacts.

17. The apparatus of claim 16, wherein said n-type material is a material selected from the group of materials consisting of Bi, Bi₂Te₃ and Se.

18. The apparatus of claim 17, said n-type material further comprising a polymer binder.

19. The apparatus of claim 16, wherein said dopant of ZT enhancing material is a material selected from the group of materials consisting of Te, Bi, and Se.

20. The apparatus of claim 16, wherein said slurry of Bi_{0.5}Sb_{1.5}Te₃, dopant and binder has a particle size ranging between 1 μm to 200 μm.
